(19) United States
(12) Patent Application Publication
(10) Pub. No.: US 2004/0121619 A1
(43) Pub. Date: Jun. 24, 2004

(54) Multipoint minute electrode, device for measuring a living organism voltage, method for fabricating the multipoint minute electrode, and method for fabricating the living organism voltage-measuring device

(75) Inventors: Hiroshi Yokoi, Sapporo City (JP); Takahiro Kawashima, Tsukuba City (JP); Eiji Makino, Hirosaki City (JP); Takayuki Shibata, Hitachi City (JP); Yukinori Kakazu, Ebetsu City (JP)

Correspondence Address: OLIFF & BERRIDGE, PLC, P.O. BOX 19928, ALEXANDRIA, VA, 22320, US

(73) Assignee: HOKKAIDO UNIVERSITY, Sapporo City (JP)

(21) Appl. No.: 10/653,218

(22) Filed: Sep. 3, 2003

(30) Foreign Application Priority Data
Dec. 20, 2002 (JP) 2002-369449

(51) Int. Cl. H01L 21/31

(52) U.S. Cl. 438/784

(57) ABSTRACT

On a given substrate are successively formed electrode patterns constituting electrode wirings for measuring points, respectively. Then, an insulating layer and an underlayer covering the electrode patterns are etched and removed to expose the substrate, which suffers from anisotropic etching using a given etching solution, to fabricate a multipoint minute electrode with a sharpened probe and a supporter for the probe.

### BACKGROUND OF THE INVENTION

1. Field of the Invention

This invention relates to a multipoint minute electrode which is preferably usable for a living organism voltage-measuring device in neuro-physiology field and the like, and a method for fabricating the multipoint minute electrode. This invention also relates to the living organism voltage-measuring device and a method for fabricating the same.

2. Description of the Related Art

In neurophysiology field, it is desired to establish a device for measuring living organism voltage. With the use of the living organism voltage-measuring device, the prove, composed of a multipoint minute electrode with a plurality of measuring points, is inserted into a minute region such as a nerve. In this point of view, it is desired that the forefront of the probe is formed sharply, but the sharpening process for the probe is very difficult by a conventional means.

For example, such an attempt is made as to alter the property of a starting material by means of B-injection, and selectively etch the starting material with an etching solution such as KOH, thereby to form a minute electrode of which the forefront is shaped sharply and which comprises a probe.

With such an etching process, however, a large scaled apparatus is required, and more, a huge facility is required. Therefore, the production cost of the sharpened minute electrode comprising the probe results in being increased. In addition, even with the above-mentioned conventional technique, it is difficult to form a desired probe composed of a sharpened minute electrode. As of now, therefore, the desired living organism voltage-measuring device can not be established.

### SUMMERY OF INVENTION

It is an object of the present invention to provide a minute electrode with the sharpened forefront easily in low cost and then, to provide a practically usable living organism voltage-measuring device.

For achieving the above object, this invention relates to a method for fabricating a multipoint minute electrode comprising a plane supporter, a sharpened probe continuously elongating from an almost center of the supporter, a plurality of measuring points being formed on a forefront of the probe, and electrode wirings for the measuring points, comprising:

a first step of forming a resist layer on an underlayer formed on a given substrate, and patterning the resist layer into a designed shape to form a resist pattern,

a second step of anisotropic-etching the underlayer via the resist pattern as a mask by using a first etching solution so as to form the etched portions therein,

a third step of forming electrode layer over the resist pattern on the underlayer,

a fourth step of removing the underlayer and the resist pattern, to form an electrode pattern constituting the electrode wirings for the measuring points of the probe,

a fifth step of forming an insulating layer on the electrode pattern,

a sixth step of partially etching and removing the insulating layer to expose the electrode pattern,

a seventh step of patterning the underlayer and the insulating layer to expose the substrate, and anisotropic etching the substrate by using a second etching solution, to form the probe sharply, and

an eighth step of forming the measuring points so as to be electrically connected to the electrode pattern.

In the present invention, two etching processes using wet etching technique are employed in the second step and the sixth step. Therefore, the forefront of the multipoint minute electrode can be easily shaped sharply in low cost. In other words, the width of the probe positioned at the forefront of the multipoint minute electrode and having measuring points can be easily narrowed to around 100 μm in low cost.

With the above-mentioned fabricating method, therefore, a multipoint minute electrode according to the present invention, which is characterized by comprising a plane supporter, a sharpened probe continuously elongating from an almost center of the supporter, a plurality of measuring points being formed on a forefront of the probe, and electrode wirings for the measuring points, can be easily provided in low cost.

Other features and advantages of the present invention will be described in detail.

### BRIEF DESCRIPTION OF THE DRAWINGS

For better understanding of the present invention, reference is made to the attached drawings, wherein

FIG. 1 is a structural view schematically showing a device for measuring a living organism voltage, according to the present invention,

FIG. 2 is an exploded view showing in magnification the measuring points of the probe of the multipoint minute electrode composing the living organism voltage-measuring device shown in FIG. 1,

FIG. 3 is a cross sectional view showing one step in a method for fabricating the multipoint minute electrode composing the living organism voltage-measuring device shown in FIG. 1, according to the present invention,

FIG. 4 is a cross sectional view showing the step after the step shown in FIG. 3,

FIG. 5 is a cross sectional view showing the step after the step shown in FIG. 4,

FIG. 6 is a cross sectional view showing the step after the step shown in FIG. 5,

FIG. 7 is a cross sectional view showing the step after the step shown in FIG. 6,

FIG. 8 is a cross sectional view showing the step after the step shown in FIG. 7,

FIG. 9 is a cross sectional view showing the step after the step shown in FIG. 8,

FIG. 10 is a cross sectional view showing the step after the step shown in FIG. 9,

FIG. 11 is a cross sectional view showing the step after the step shown in FIG. 10,

FIG. 12 is a cross sectional view showing the step after the step shown in FIG. 11,

FIG. 13 is a cross sectional view showing the step after the step shown in FIG. 12,

FIG. 14 is a cross sectional view showing the step after the step shown in FIG. 13, and

FIG. 15 is a cross Rational view showing the step after the step shown in FIG. 14.

### DESCRIPTION OF THE PREFERRED EMBODIMENTS

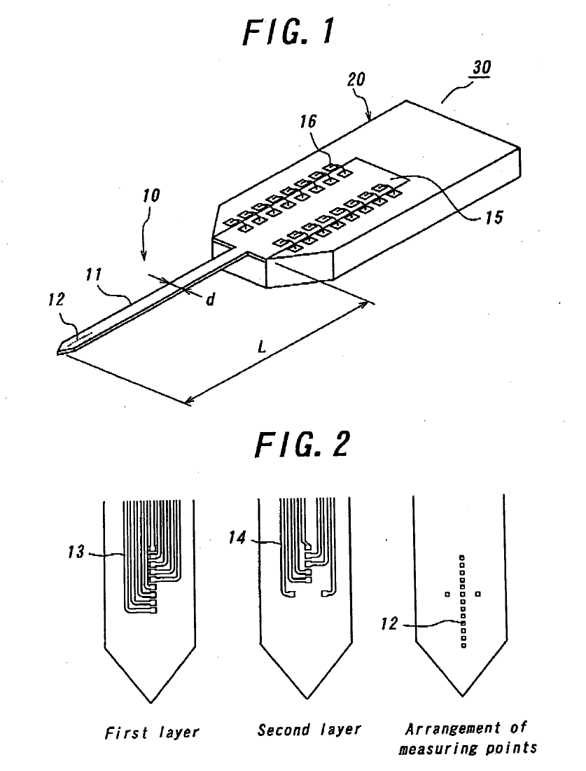

This invention will be described in detail with reference to the accompanying drawings. FIG. 1 is a structural view schematically showing a device for measuring a living organism voltage, according to the present invention. The living organism voltage-measuring device 30 shown in FIG. 1 includes a multipoint minute electrode 10 and a connector 20. The multipoint minute electrode 10 includes a plane supporter 15 and a sharpened probe 11 elongating from the almost center of the supporter 15. At the forefront of the probe 11 are formed a plurality of measuring points 12, and at the supporter 15 is formed a plurality of electrode pads 16 to electrically connect between the multipoint minute electrode 10 and the connector 20 via wires.

FIG. 2 is an exploded view showing in magnification the area encompassing the measuring points 12 of the probe 11 of the multipoint minute electrode 10 composing the living organism voltage-measuring device 30. As shown in FIG. 2, the probe 11 has a multilayered structure, and electrode wirings 13 and 14 for the measuring points 12 are formed on the first layer and the second layer separately and thus in multistage. At the top layer are formed the measuring points 12 so as to be electrically connected to the electrode wirings 13 and 14. In this embodiment, as apparent from FIG. 2, nine electrode wirings 13 are formed on the first layer, and seven electrode wirings 14 are formed on the second layer, and 16 measuring points 12 are formed on the top layer so as to be electrically connected to the electrode wirings 13 and 14.

In this way, if the electrode wirings are formed in multistage, measuring points to be electrically connected to the electrode wirings can be formed and arranged in high density. With the use of the living organism voltage-me device 30 mounting the probe 11 with high density-arranged measuring points 12, the living organism voltage can be measured precisely.

The measuring points 12 and the electrode pads 16 provided on the supporter 15 are electrically connected with the electrode wirings 13 and 14.

In the living organism voltage-measuring device 30 shown in FIG. 1, the width “d” of the probe 11 of the multipoint minute electrode 10 can be easily narrowed to 100 μm or below in low cost by means of the fabricating method of the present invention. The length “L” of the probe 11 is set within 1000-5000 μm.

The measuring points 12 are preferably made of Pt stably and inactively in a living organism. Also, the measuring points 12 may be made of another Pt-based material containing an additional element. The electrode wirings 13 and 14 are preferably made of a Pt-based material, as the measuring points 12, so as to realize good electric contact for the measuring points 12. For example, a multilayered structure of Ti layer/Pt layer/Ti layer may be employed as the Pt-based material.

The size of each measuring point 12 may be set to 15 μM square. The line width and the line space of the electrode wirings 13 and 14 may be set to 15 μm and 10 μm, respectively.

The multipoint minute electrode 10 with the sharpened probe 11 composing the living organism voltage-measuring device 30 can be fabricated by means of the fabricating method of the present invention as follows.

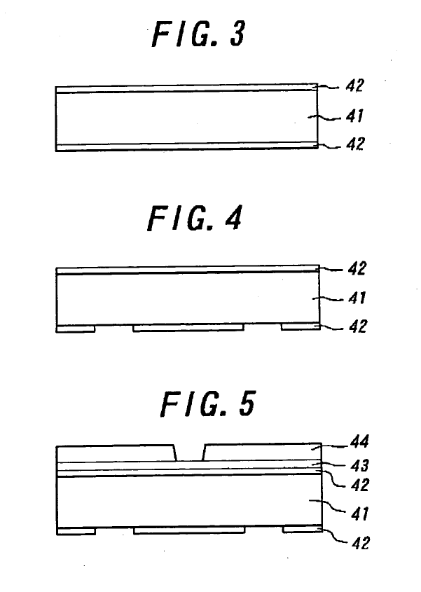

FIGS. 3-15 are cross sectional views showing the steps in the fabricating method of the present invention, taken on the line perpendicular to the electrode wirings 13 and 14 illustrated in FIG. 2.

As shown in FIG. 3, first of all, a (001) silicon substrate 41 is prepared, and thermal oxidized films (SiO₂ films) are formed, e.g., in a thickness of 2 μm on both surfaces of the silicon substrate 41. Then, as shown in FIG. 4, the thermal oxidized film 42 formed on the bottom surface of the silicon substrate 41 is patterned by using a buffering hydrofluoric acid solution. Then, as shown in FIG. 5, a nickel underlayer 43 and a resist layer are successively formed on the top surface of the silicon substrate 41 via the thermal oxidized film 42, and the resist layer is patterned to form a patterned layer 44.

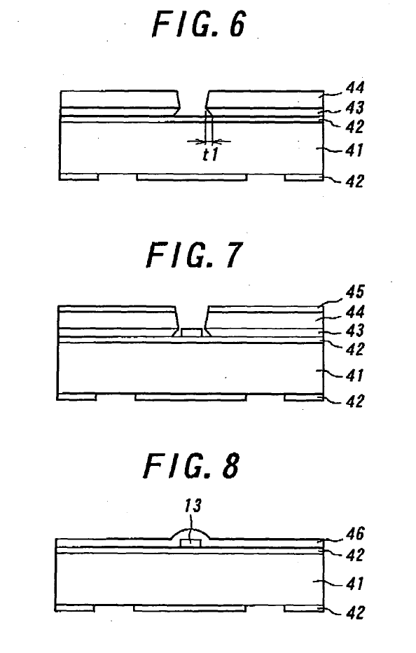

Then, as shown in FIG. 6, the nickel underlayer 43 is anisotropic-etched with a first etching solution using the patterned layer 44 as a mask so as to form side etched portions therein from the patterned layer 44. The depth “t1” of the side etched portion is set within 2-5 μm.

As the first etching solution, any kind of solution can be employed, but iron chloride solution can be preferably employed. With the use of the iron chloride solution, the side etched portions can be made easily. Concretely, if the anisotropic etching is performed with 7% iron chloride solution at 30° C., the side etched portion with a depth of about 2 μm can be easily formed.

Then, as shown in FIG. 7, an electrode layer 45 is formed over the patterned layer 44 by means of a conventional film-forming method such as vacuum deposition. Since the electrode layer 45 is processed into the electrode wirings 13 for the measuring points 12, it is made of the Pt-based material such as the multilayered structure of Ti layer/Pt layer/Ti layer, as mentioned above.

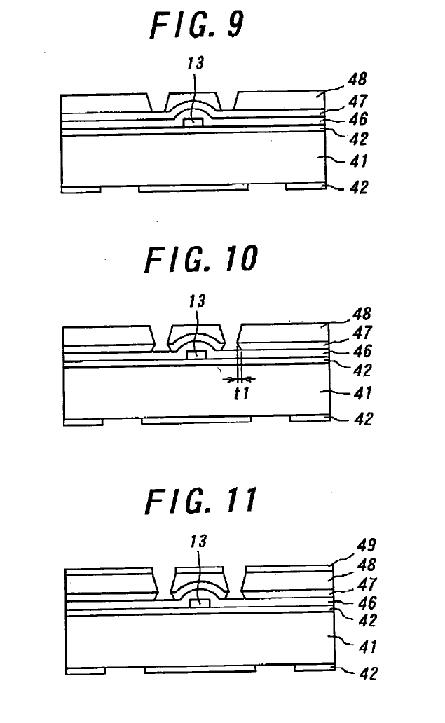

Then, as shown in FIG. 8, the nickel underlayer 43 and the patterned layer 44 are removed with iron chloride solution or the like, to form electrode patterns 13 (electrode wirings on first layer). Then, an insulating layer 46 made of SiO₂, etc., is formed over the electrode pattern 13. Then, as shown in FIG. 9, a nickel underlayer 47 and a patterned layer 48 arc formed on the insulating layer 46 in the same manner as shown in FIG. 5. Then, as shown in FIG. 10, anisotropic etching is performed for the nickel underlayer 47 by using iron chloride solution in the same manner as shown in FIG. 6 to form side etched portions in the nickel underlayer 47. The depth “t2” of the side etched portion is set within 2-5 μm.

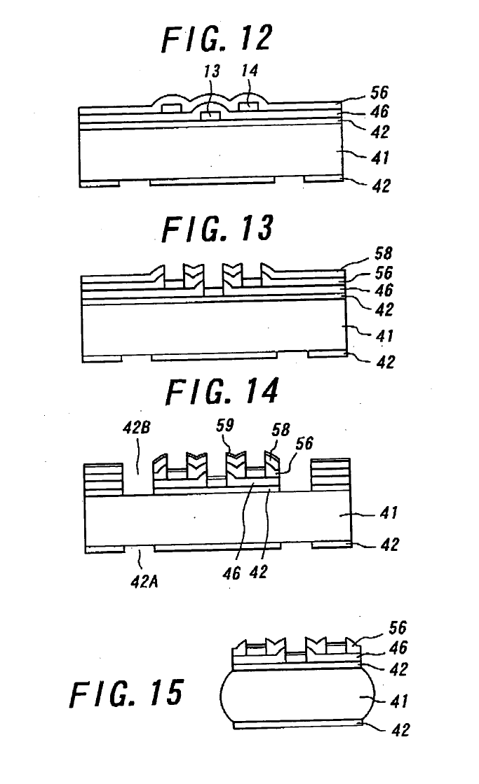

Then, as shown in FIG. 11, an electrode layer 49 is formed over the patterned layer 48 in the same manner as shown in FIG. 7. Since the electrode layer 49 is processed into the electrode wirings 14 for the measuring points 12, it is made of the Pt-based material such as the multilayered structure of Ti layer/Pt layer/Ti layer. Then, as shown in FIG. 12, the nickel underlayer 47 and the patterned layer 48 is removed by using iron chloride solution to form electrode patterns 14 (electrode wiring on second layer). Then, an insulating layer 56 is formed over the electrode pattern 14.

Then, as shown in FIG. 13, a mask layer 58 is formed of resist on the insulating layer 56, and the electrode patterns 13 and 14 are exposed by means of etching using a buffering hydrofluoric acid solution via the mask layer 58. Then, as shown in FIG. 14, a cap layer 59 is made of a multilayered structure of Pt layer/Ti layer, and portions of the thus obtained multilayered body corresponding to the openings 42A of the thermal oxidized film 42 on the bottom surface of the silicon substrate 41 are etched and removed to form openings 42B. Then, the mask layer 58 is removed, and the resultant multilayered body shown in FIG. 14 is anisotropic-etched from the openings 4A and 42B by using a second etching solution, to form an assembly shown in FIG. 15.

As the second etching solution, any kind of solution can be employed, but tetramethylammonium hydroxide (TMAH) can be preferably employed. In this case, the anisotropic etching can be performed under good condition, the intended assembly can be easily formed in body-protuberated shape as shown in FIG. 15.

Thereafter, the measuring points 12 are formed of the Pt-based material so as to be electrically connected to the electrode patterns 13 and 14, to form the multipoint minute electrode 10 as shown in FIG. 1.

The electrode pads 16 can be formed in the measuring points-forming process as mentioned above so as to be electrically connected to the electrode patterns 13 and 14. In this case, the portions for forming the electrode pads 16 are formed in advance in the step shown in FIG. 13 through the anisotropic etching.

After the multipoint minute electrode 10 is fabricated, the connector 20 is formed so as to support the supporter 15 of the electrode 10, and the electrode pads 16 and the connector 20 are electrically connected with wires, thereby to fabricate the living organism voltage-measuring device 30 shown in FIG. 1.

Although the present invention was described in detail with reference to the above examples, this invention is not limited to the above disclosure and every kind of variation and modification may be made without departing from the scope of the present invention.

In the above embodiment, for example, the silicon substrate is employed, but any other substrate may be employed. Therefore, the steps shown in FIGS. 3 and 4 are not essential in the present invention, but may be omitted on the kind of substrate to be employed.

As mentioned above, according to the present invention, a minute electrode with the sharpened forefront can be easily provided in low cost and then, a practically usable living organism voltage-measuring device can be provided on the multipoint minute electrode.

What is claimed is:

1. A multipoint minute electrode, comprising:
a plane supporter,
a sharpened probe continuously elongating from an almost center of said supporter, a plurality of measuring points being formed on a forefront of said probe, and
electrode wirings for said measuring points.

2. The multipoint minute electrode as defined in claim 1, wherein the width of said probe is set to 100 μm or below.

3. The multipoint minute electrode as defined in claim 1, wherein at least said forefront of said probe is structured in multilayered shape, and said electrode wirings are disposed in multistage in layers constituting said multilayered forefront of said probe.

4. The multipoint minute electrode as defined in claim 1, further comprising electrode pads to be electrically connected to said measuring points on a top surface of said supporter.

5. The multipoint minute electrode as defined in claim 1, wherein said measuring points includes Pt.

6. The multipoint minute electrode as defined in claim 3, wherein said electrode wirings includes pt.

7. The multipoint minute electrode as defined in claim 6, wherein said electrode wirings includes a multilayered structure with a Pt layer.

8. A device for measuring a living organism voltage, comprising:
a multipoint minute electrode as defined in claim 1, and
a connector to support a supporter of said multipoint minute electrode.

9. A method for fabricating a multipoint minute electrode comprising a plane supporter, a sharpened probe continuously elongating from an almost center of said supporter, a plurality of measuring points being formed on a forefront of said probe, and electrode wirings for said measuring points, comprising:
a first step of forming a resist layer on an underlayer formed on a given substrate, and patterning said resist layer into a designed shape to form a resist pattern,
a second step of anisotropic-etching said underlayer via said resist pattern as a mask by using a first etching solution so as to form side etched portions therein,
a third step of forming electrode layer over said resist pattern on said underlayer,
a fourth step of removing said underlayer and said resist pattern, to form an electrode pattern constituting said electrode wirings for said measuring points of said probe,
a fifth step of forming an insulating layer on said electrode pattern,
a sixth step of partially etching and removing said insulating layer to expose said electrode pattern,
a seventh step of patterning said underlayer and said insulating layer to expose said substrate, and anisotropic etching said substrate by using a second etching solution, to form said probe sharply, and
an eighth step of forming said measuring points so as to be electrically connected to said electrode pattern.

10. The fabricating method as defined in claim 9, wherein said underlayer includes nickel.

11. The fabricating method as defined in claim 9, wherein said first etching solution is iron chloride solution.

12. The fabricating method as defined in claim 9, wherein said electrode layer includes Pt.

13. The fabricating method as defined in claim 12, wherein said electrode layer includes a multilayered structure with a pt layer.

14. The fabricating method as defined in claim 9, wherein said measuring points includes Pt.

15. The fabricating method as defined in claim 9, wherein said second etching solution is tetramethylammonium hydroxide (TMAH).

16. The fabricating method as defined in claim 9, wherein said first step through said sixth step are defined as one cycle process, and said electrode pattern is shaped in multistage by repeating said cycle process, to form in multistage said electrode wirings of said probe of said multipoint minute electrode.

17. The fabricating method as defined in claim 9, further comprising an additional step of forming electrode pads on a top surface of said supporter of said multipoint minute electrode.

18. The fabricating method as defined in claim 9, wherein the width of said probe of said multipoint minute electrode is set to 100 μm or below.

19. A method for fabricating a living organism voltage-measuring device, comprising the steps of:
fabricating a multipoint minute electrode by a fabricating method as defined in claim 9, and
forming a connector so as to support a supporter of said multipoint minute electrode.
